(19) United States
(12) Patent Application Publication
(10) Pub. No.: US 2007/0273403 A1
(43) Pub. Date: Nov. 29, 2007

(54) Clock Tree For Programmable Logic Array Devices

(76) Inventor: Tai-Cheng Wang, Hsinchu City (TW)

Correspondence Address: LIN & ASSOCIATES INTELLECTUAL PROPERTY, INC., P.O. BOX 2339, SARATOGA, CA, 95070-0339, US

(21) Appl. No.: 11/420,478

(22) Filed: May 26, 2006

(51) Int. Cl. H03K 19/177

(52) U.S. Cl. 326/41

(57) ABSTRACT

A clock tree for PLAD is provided, with each logic element having an embedded circuit having a buffer connecting vertical bus wires to horizontal bus wires so that the clocks on each horizontal bus wire are synchronized, because the every horizontal wire gets the same capacitor and the same clock propagation gate delay, and the clock signals among the logic elements have the minimal clock skew.

### FIELD OF THE INVENTION

The present invention generally relates to a programmable logic array device, and more specifically to a clock tree design of a programmable logic array device.

### BACKGROUND OF THE INVENTION

The programmable logic array device (PLAD) is an electronic component that is used built digital circuits. The core of the PLAD is a programmable logic array (PLA), consisting of a set of programmable combinatory logic and flip/flop (F/F). Because the layout of the PLA can be used to implement general logic functions which can be synthesized the combinatory logic and flip/flop. Unlike a logic gate, which has a fixed function, a PLAD has an undefined function at the time of manufacture. Before the PLAD can be used in a circuit it must be programmed. Various forms of programmable logic array devices, including PAL, GAL, CPLD, FPGA, have been developed throughout the years.

There has been an ongoing interest in reconfigurable systems, which includes a microprocessor circuit containing some fixed functions and other functions that cane be altered by code running on the processor. Due to the innate flexibility of the PLAD, PLAD is often sold as a microprocessor with a fixed core function surrounded by programmable logic. These devices allow the designer to concentrate on adding new features to his design without having to worry about making the microprocessor work.

Clock signals are important and usually difficult to the design of PLAD because clock signals are typically loaded with fanout, travel over distances, and operate at high speeds of any signal, either control or data, within the entire synchronous system. Furthermore, these clock signals are particularly affected by technology scaling, in that long global interconnect lines become significantly more resistive as line dimensions are decreased. This increased line resistance is one of the primary reasons for the increasing significance of clock distribution on synchronous performance. Finally, the control of any differences and uncertainty in the arrival times of the clock signals can severely limit the maximum performance of the entire system, as tiny differences in propagation delay, when compounded across all the clock nets in a complex digital product, often lead to unacceptable degradations in overall system-timing margins. This generic problem, often referred to as the “clock skew” problem, can create catastrophic race conditions in which an incorrect data signal may latch within a register. The proper design of the clock tree of synchronous digital systems must ensure that these critical timing requirements are satisfied and that no race conditions exist.

Taiwan Patent No. 1246003 disclosed a method for dynamic balancing of a clock tree. The method includes inserting a controllable buffer to a level of a clock tree, providing a controller to control the layout of the PMOS/NMOS of the controllable buffer to adjust the two clocks of different phases, and generating more current to compensate the delay in the slow clock. The method is used in synchronous circuit design to compenstae the clock skew due to voltage drop or the temperature changes.

Taiwan Patent No. 1240191 disclosed a method for EDA tools to bypass a plurality of clock branches in the EDA tools. The method includes measuring the delay of the components to the clock, and forming a buffer to act as a delay to the clock caused by the component.

However, clock skew minimization remains a challenge to the design and the performance of a large-scaled high speed PLAD.

### SUMMARY OF THE INVENTION

The present invention has been made to overcome the above-mentioned drawback of clock tree of PLAD. The primary object of the present invention is to provide a circuit design of a clock tree that has the minimal clock skew in a synchronous PLAD system.

To achieve the above object, the present invention provides a PLA with each logic element having a buffer connecting vertical bus wires to horizontal bus wires so that the clocks on each horizontal bus wire are synchronized, and the clock signals among the logic elements have the minimal clock skew.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic view of a PLAD of the present invention; and

FIG. 2 shows a schematic view of an embodiment of a logic element of the present invention.

### DETAILED DESCRIPTION OF THE PREFERRED EMBODIMENTS

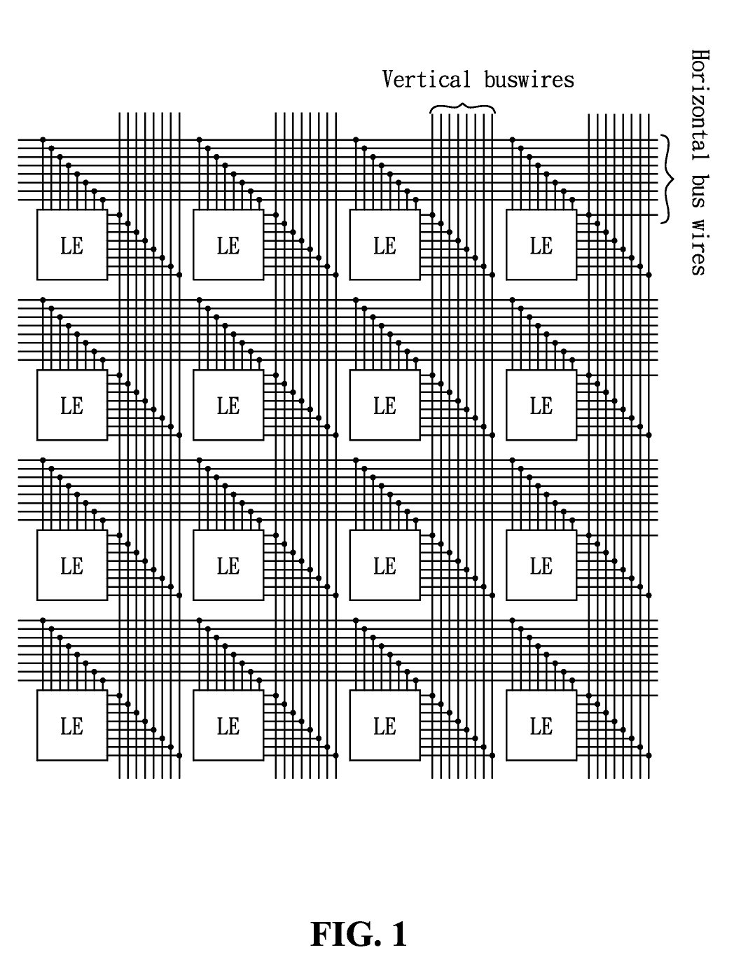

FIG. 1 shows a schematic view of programmable logic array device of the present invention. As shown in FIG. 1, a PLAD includes a plurality of rows and a plurality of columns of logic elements LE_{i,j}, where i and j indicate the i-th row and j-th column. FIG. 1 shows an embodiment including a 4×4 array of logic element. However, the present invention can be expanded to a larger size. For a 4×4 array in this embodiment, there are 8 vertical bus wires and 8 horizontal bus wires. Each column of logic elements is connected to 2 vertical bus wires as output, and each row of logic elements is connected to 2 horizontal wires as output. Thus, a 4×4 PLAD requires 8 vertical bus wires and 8 horizontal bus wires. On the other hand, each logic element LE_{i,j} has all 8 vertical bus wires and 8 horizontal bus wires as input.

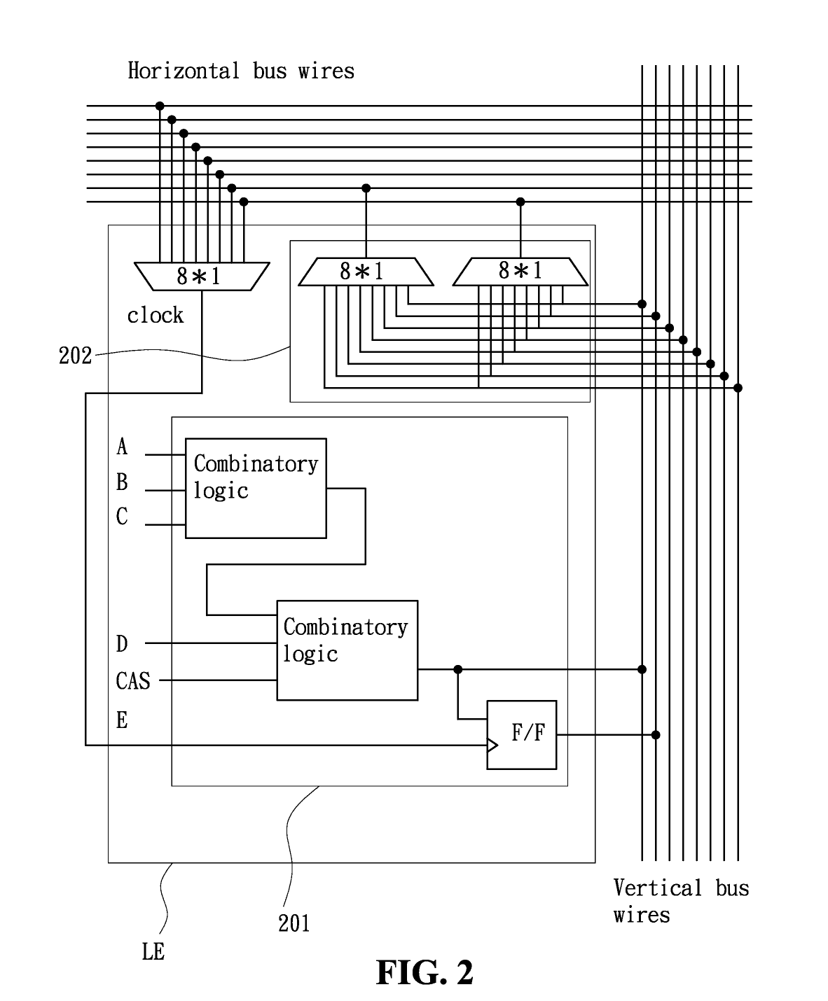

FIG. 2 shows a schematic view of an embodiment of a logic element of the present invention. As shown in FIG. 2, a logic element includes a combinatory logic unit 201 and a clock buffer unit 202. Combinatory logic unit 201 further includes a plurality of combinatory logic and flip/flop to implement the desired functions. For example, the embodiment of combinatory logic unit 201 in FIG. 2 includes two 3-input logic units and a flip/flop connected so that the logic elements can implement a function that receives 5 inputs A,B,C,D,E, a cascade input CAS from a previous stage, and outputs two results to two vertical bus wires. Clock buffer unit 202 further includes two buffers, with each buffer connecting the 8 vertical bus wires to a horizontal bus wire. For example, each buffer can be implemented with an 8-to-1 multiplexer.

For operation, any vertical wire bus and horizontal wire bus can be used as a clock tree to propagate the clock signals to each logic element in the PLAD. For example, if logic element LE_{i,j} computes and outputs the clock signal to vertical bus wire 2j, clock buffer unit 202 of each logic element will propagate clock signal on vertical wire bus 2j to a horizontal bus wire, which can act as the clock input to each logic element.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A structure for a programmable logic array device with clock tree, comprising:
a plurality of logic elements arranged in rows and columns;
a plurality of vertical bus wires connecting to each column of said logic elements; and
a plurality of horizontal bus wires connecting to each row of said logic elements;
where each said logic element of a column connected to 2 said vertical bus wires as outputs so that the number of said vertical bus wires being two-times of the number of said logic elements in a column, and each said logic element of a row connected to 2 said horizontal wires as outputs so that the number of said horizontal bus wires being two-times of the number of said logic elements in a row, while each said logic element having all said vertical bus wires and said horizontal bus wires as inputs.

2. The structure as claimed in claim 1, wherein said logic element further comprises:
a combinatory logic unit, further comprising a plurality of combinatory logic and flip/flop to implement the desired functions; and
a clock buffer for buffer clock signals from said vertical bus wire to said horizontal bus wire, each buffer being implemented with an N-to-1 multiplexer.

3. The structure as claimed in claim 2, wherein said clock buffer unit further comprises two buffers.

4. The structure as claimed in claim 3, wherein said buffer can be implemented with a multiplexer of said vertical bus wires to said horizontal bus wires.

5. The structure as claimed in claim 4, wherein every said horizontal line has the same capacitance and the same propagation gate delay clock path to every clock input of said flip/flop.
